(19) United States
(12) Patent Application Publication
(10) Pub. No.: US 2026/0221967 A1
(43) Pub. Date: Jul. 30, 2026

(54) APPARATUS AND METHOD FOR HIGH LINEARITY SLEW ENHANCEMENT ON AN OUTPUT BUFFER

(71) Applicant: Analog Devices, Inc., Wilmington, MA (US)

(72) Inventor: Michael Brian ANDERSON, Colorado Springs, CO (US)

(21) Appl. No.: 19/038,333

(22) Filed: Jan. 27, 2025

(51) Int. Cl. H03K 17/56; H03K 5/02

(52) U.S. Cl. CPC H03K 17/56; H03K 5/02

(57) ABSTRACT

Aspects of the present disclosure provide for apparatuses, which may be highly linear precision output buffers, with enhanced slew rates. An apparatus in accordance with the present disclosure may comprise a first transistor, a second transistor, coupled in cascode to the first transistor, a biasing source, coupled to the second transistor, a replica device, coupled to the first transistor, and a comparator, coupled to the biasing source and the replica device, wherein a slew rate of the first transistor is controlled based on a current through the replica device.

### BACKGROUND

### Technical Field

The present disclosure generally relates to an output buffer, and more particularly to a high slew rate of a highly linear output buffer.

### Introduction

Electronic devices often use multiplexers and output buffers to route and regulate signals within a device. Many devices set voltage levels for comparison, switching, and buffering of signals.

Devices may also use analog-to-digital (A/D) converters to allow for digital control and computation. Further, devices may output data serially in groups, called frames, which repeat periodically. In order to properly react to incoming data, the converters and overall devices must react within certain time limits.

Switching between voltages within devices takes a certain amount of time, depending on the capacitive and resistive loads coupled to the device, as well as the capacitive and resistive impedances within the device itself. Further, when voltages are switched, some settling time is required to allow the switched voltage to resolve at the new desired voltage level. As devices reduce their response time, switching between voltages, and the settling of voltages at new levels, may limit the speed of the overall device.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

The present disclosure provides methods and apparatuses for controlling the slew rate of a highly linear output buffer and/or an amplifier.

An apparatus in accordance with the present disclosure may comprise a first transistor, a second transistor, coupled in cascode to the first transistor, a biasing source, coupled to the second transistor, a replica device, coupled to the first transistor, and a comparator, coupled to the biasing source and the replica device, wherein a slew rate of the first transistor is controlled based on a current through the replica device.

Such an apparatus further optionally comprises a geometry of the replica device being similar to a geometry of the first transistor, the comparator comparing a current through the biasing source with a threshold current, when the current through the biasing source and a current through the replica device is greater than the threshold current, a voltage at a gate of the first transistor is changed to increase a current through the first transistor, and when the current through the biasing source and the current through the replica device is less than the threshold current, the voltage at the gate of the first transistor is changed to decrease the current through the first transistor.

Such an apparatus further optionally comprises a third transistor, a fourth transistor coupled in cascode with the third transistor, and a second replica device coupled to the fourth transistor, wherein a slew rate of the third transistor is controlled based on a current through the second replica device.

Such an apparatus further optionally comprises a geometry of the second replica device being similar to a geometry of the third transistor, the comparator comparing a current through the biasing source with a threshold current, when the current through the biasing source and a current through the second replica device is greater than the threshold current, a voltage at a gate of the fourth transistor is changed to increase a current through the fourth transistor, and when the current through the biasing source and the current through the second replica device is less than the threshold current, the voltage at the gate of the fourth transistor is changed to decrease the current through the fourth transistor.

An output buffer in accordance with an aspect of the present disclosure may comprise an amplifier, comprising a first transistor and a second transistor coupled in cascode, an output of the amplifier comprising an output of the output buffer, a current source coupled to the amplifier for biasing the amplifier, a replica device, coupled to the amplifier, wherein the replica device receives an input to the output buffer, and a comparator, coupled to the replica device and the current source, wherein a slew rate of the amplifier is controlled based at least on a current through the replica device.

Such an output buffer further optionally comprises a geometry of the replica device being similar to a geometry of the first transistor, the comparator comparing a current through the current source with a threshold current, when the current through the current source and a current through the replica device is greater than the threshold current, a voltage at a gate of the first transistor is changed to increase a current through the first transistor, and when the current through the current source and the current through the replica device is less than the threshold current, the voltage at the gate of the first transistor is changed to decrease the current through the first transistor.

Such an output buffer further optionally comprises a third transistor, a fourth transistor coupled in cascode with the third transistor, the third transistor coupled to the output of the output buffer, and a second replica device coupled to the fourth transistor, wherein a slew rate of the third transistor is controlled based on a current through the second replica device.

Such an output buffer further optionally comprises a geometry of the second replica device being similar to a geometry of the third transistor, the comparator comparing a current through the biasing source with a threshold current, when the current through the biasing source and a current through the second replica device is greater than the threshold current, a voltage at a gate of the fourth transistor is changed to increase a current through the fourth transistor, and when the current through the biasing source and the current through the second replica device is less than the threshold current, the voltage at the gate of the fourth transistor is changed to decrease the current through the fourth transistor.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

FIG. 1 is a schematic diagram of a system in accordance with an exemplary aspect of the present disclosure.

FIG. 2 is a schematic diagram of an amplifier in accordance with an exemplary aspect of the present disclosure.

FIG. 3 is a schematic diagram of an amplifier in accordance with an aspect of the present disclosure.

FIG. 4 is a pair of corresponding graphs of a voltage waveform over time for an amplifier in accordance with an aspect of the present disclosure.

FIG. 5 is a schematic diagram of a circuit in accordance with an aspect of the present disclosure.

FIG. 6 is a schematic diagram of a circuit in accordance with an aspect of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

The present disclosure includes apparatuses and methods for controlling the slew rate of an output buffer and/or an amplifier.

### Overview

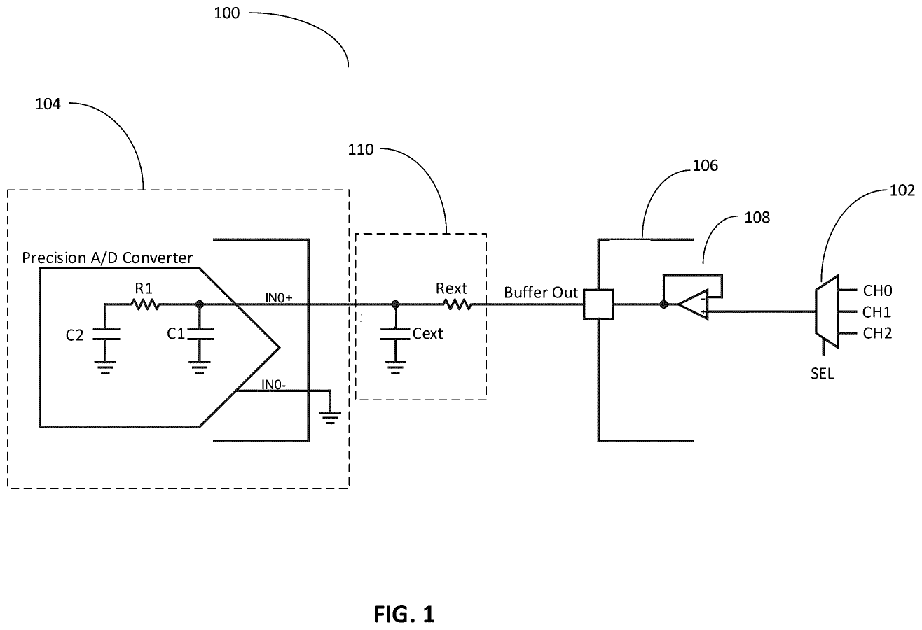

Referring to FIG. 1, a system 100 in accordance with an exemplary aspect of the present disclosure may include one or more multiplexers (mux) 102, one or more converters 104, a voltage 106, a buffer 108, and a resistor-capacitor (RC) network 110. System 100 may be used to allow for the reading of various input signals in a rapid manner.

Mux 102 allows for various signals, e.g., different data streams, different incoming signals, etc., to be selectively switched as inputs to the remainder of system 100.

Converter 104, which may be an A/D converter, allows for the various signals coming from mux 102 to be placed into a consistent format, e.g., digital format, analog format with a consistent voltage range, etc.

Voltage 106 sets a voltage level for RC network 110. Buffer 108 allows for different voltage levels from mux 102 to feed RC network 110. RC network 110 can be used to filter a signal from mux 102 by blocking certain frequencies and passing other frequencies. In some instances, RC network 110 can be used as a high-pass filter and in other instances, RC network 110 can be used as a low-pass filter.

In an aspect of the present disclosure, a plurality of different mux 102 may be coupled in system 100, and to turn on/turn off each mux 102, one mux 102 must be turned on and another mux 102 must be turned off, and this transition must occur and settle fast enough for converter 104 to maintain data continuity within system 100. For example, and not by way of limitation, voltage 106, and/or the voltage output of buffer 108, may have to transition from 0 volts to 4.096 volts, or from 4.096 volts to 0 volts, and may have to settle at the new voltage within a certain amount of time to allow for converter 104 to operate on the inputs from the various mux 102 as desired. The time for voltage 106 and/or the voltage output of buffer 108 to settle to the desired voltage may be between 300 and 1000 nanoseconds, such as 500 nanoseconds, 700 nanoseconds, but the settling time may be larger or smaller as desired to have system 100 operate as desired.

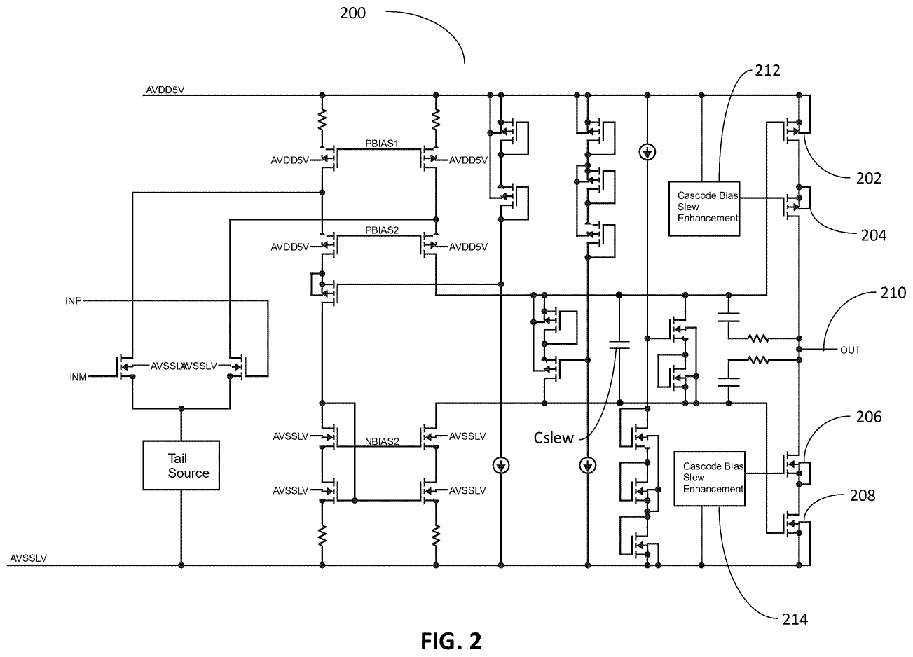

Referring to FIG. 2, an amplifier 200 in accordance with an exemplary aspect of the present disclosure includes components for controlling a slew rate of the highly linear amplifier.

Amplifier 200 is a folded cascode amplifier, with a first transistor 202 and a second transistor 204 connected in cascode. Amplifier 200 also comprises a third transistor 206 connected in cascode with fourth transistor 208, and output 210 of amplifier 200 is coupled between second transistor 204 and third transistor 206.

Amplifier 200, in an aspect of the present disclosure, also includes a cascode bias slew enhancement 212 to change the slew rate of the cascode coupled first transistor 202 and second transistor 204. Amplifier 200, in an aspect of the present disclosure, also includes a cascode bias slew enhancement 214 to change the slew rate of the cascode coupled third transistor 206 and fourth transistor 208.

Cascode bias slew enhancement 212 and/or cascode bias slew enhancement 214 may provide a faster turn-on/turn-off of the voltage from voltage 106 and/or the voltage output of buffer 108 than a system without slew enhancement circuitry to allow for a desired turn-off time. For example, and not by way of limitation, cascode bias slew enhancement 212 may provide an output voltage change from 0 volts to 4.096 volts in under 700 nanoseconds. Cascode bias slew enhancement 212 and/or cascode bias slew enhancement 214 may allow for the cascode connected transistors to have very high current flow, e.g., cascode bias slew enhancement 212 may drive the second transistor 204 deep into the active region, i.e., have higher drain current than in normal operating conditions, to reduce the possibility that second transistor 204 enters the saturation region during any turn-on and/or turn-off transitions. In such an aspect of the present disclosure, the amplifier 200 slew rate may be modified to allow for faster transitions between voltages and changes between muxes coupled to amplifier 200.

In an aspect of the present disclosure, the gate of e.g., second transistor 204, is the control for this high drain current condition. Because the gate current in a field-effect transistor is typically small, a large power draw for the slew rate control used by cascode bias slew enhancement 212 (and similarly for cascode bias slew enhancement 214) may be avoided. Component Cslew may mitigate coupling between first transistor 202 and fourth transistor 208.

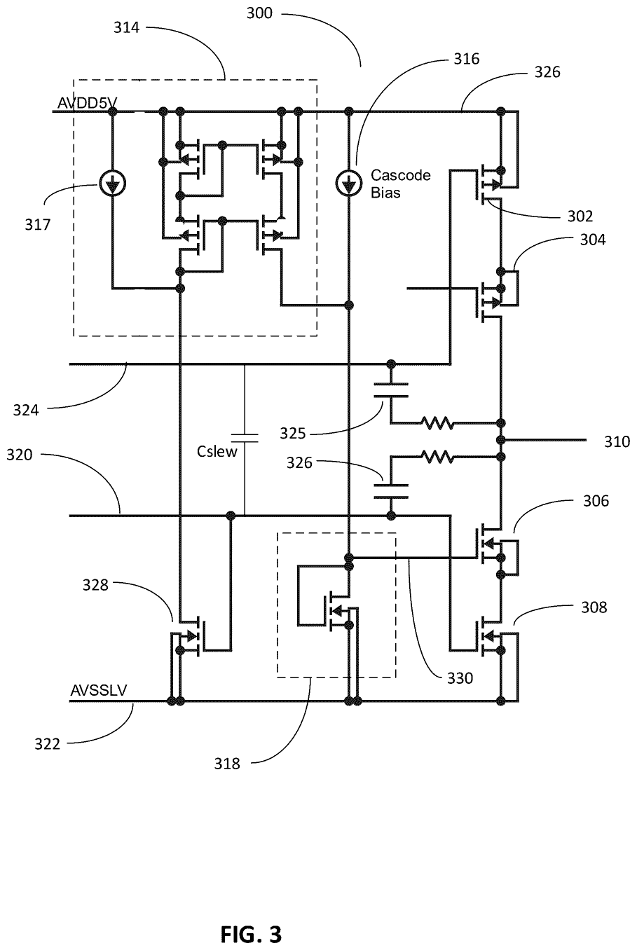

Referring to FIG. 3, an amplifier 300 in accordance with an aspect of the present disclosure includes components for controlling a slew rate of the amplifier 300. Amplifier 300 may include first transistor 302 and second transistor 304 connected in cascode. Further, amplifier 300 may include third transistor 306 and fourth transistor 308 connected in cascode, with output 310 coupled between second transistor 304 and third transistor 306. As shown in FIG. 3, comparator 314 is coupled to the gate of first transistor 306. Current comparator 314 compares the current between cascode bias 328 and current source 317, and may control the gate voltage of third transistor 306.

First transistor 302 and fourth transistor 308 may be referred to as “output transistors” while second transistor 304 and third transistor 306 may be referred to as “cascode transistors” in the configuration shown in FIG. 3. Further, first transistor 302 may be similar to first transistor 202, second transistor 304 may be similar to second transistor 204, third transistor 306 may be similar to third transistor 206, and fourth transistor 308 may be similar to fourth transistor 208. By maintaining a low VDS across first transistor 302 and fourth transistor 308, the output will be highly linear across a wide range. Thus second transistor 304 and third transistor 306 are biased in such a way to provide a low VDS across first transistor 302 and fourth transistor 308 while keeping first transistor 302 and fourth transistor 308 in the forward active region.

In operation, amplifier 300 may have a cascode bias 316, which may be set to allow for operation of the cascode devices, i.e., first transistor 302, second transistor 304, third transistor 306, and fourth transistor 308. The cascode bias 316 may be set at a level to develop a VGS across bias transistor 318 and set the VDS of fourth transistor 308 to achieve high linearity. Bias transistor 318 is shown as an example of a diode connected MOSFET, and is coupled to the gate of third transistor 306.

To drive the output 310 to a “low” (typically 0 volts) condition, a signal on line 320 is driven to a “high” condition. Line 320 is connected to the gate of fourth transistor 308, which turns fourth transistor “on,” i.e., allows current flow through fourth transistor 308. This produces a strong pull down from output 310 to line 322, which may be coupled to a 0 volt reference or local ground for amplifier 300.

To drive the output 310 to a high condition, a signal on input 324 is driven to a low condition. This signal then turns on the gate of first transistor 302 to allow for a strong pull-up condition between input 324, which may be coupled to a higher potential, e.g., 5 volts, thus driving the output 310 to a higher voltage potential or “high” condition.

During transition of output 310 from a high condition to a low condition, an increased voltage on line 320 may provide a large amount of current through third transistor 306 and fourth transistor 308. The voltage across third transistor 306 will increase, which reduces the voltage across fourth transistor 308. This condition then takes fourth transistor 308 out of saturation, slowing fourth transistor 308 down and increasing the time to transition between the high condition and the low condition for output 310. This decreases the “slew” rate for the amplifier 300.

In an aspect of the present disclosure, the operating condition of third transistor 306 is changed slightly while fourth transistor 308 is maintained in the active region to allow for a faster switching of the voltage at output 310. The current through first transistor 302, second transistor 304, third transistor 306, and fourth transistor 308 may be a static or constant current, and no current will be flowing through output 310 once the output 310 voltage level is set to the desired voltage. When the output 310 voltage changes, either first transistor 302 and second transistor 304, or third transistor 306 and fourth transistor 308, will turn on or off to change the output 310 voltage. Once capacitor 325 and 326 reach their steady-state voltages, no additional current will flow from output 310.

To achieve the change in operating conditions for, e.g., third transistor 306 and fourth transistor 308, a larger voltage drop across fourth transistor 308 may be desired. In an aspect of the present disclosure, changing the gate drive on the third transistor 306 to provide a larger voltage drop across fourth transistor 308 will help drive fourth transistor 308 deeper into the active region and allow additional current to flow through third transistor 306 and fourth transistor 308. By increasing the voltage across fourth transistor 308, fourth transistor 308 will remain fully in the active region and not come out of current saturation, which would speed up the slew rate of the amplifier 300, i.e., the time that it takes amplifier 300 to change output 310 voltage from low to high or from high to low.

To change the conditions for e.g., fourth transistor 308, the change in operating condition for third transistor 306 may occur for a short period of time to slew the voltage across fourth transistor 308 and then the operating condition for third transistor 306 will remain constant at a given voltage level. Once the desired output voltage is produced, the slew enhancement circuits turn-off reducing the VDS of first transistor 302 and fourth transistor 308 to achieve a highly linear output voltage on output 310.

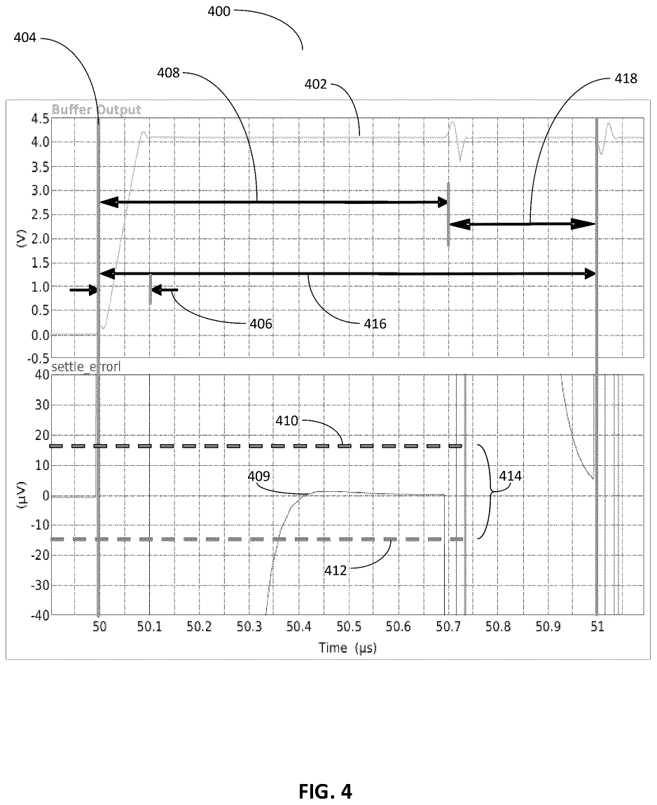

Referring to FIG. 4, a stacked pair of voltage graphs 400 of an amplifier in accordance with an aspect of the present disclosure having a waveform 402, which is the voltage across third transistor 306 during an output 310 state transition from high to low voltage. In this case, the stacked pair of voltage graphs 400 include the lower graph being a magnified version of the upper graph, as indicated by the smaller voltage scale of the lower graph (e.g., μV versus V). The transition from a low voltage, e.g., 0 volts across third transistor 306, begins at time 404 and has a duration of time 406. In an aspect of the present disclosure, time 406 may be 100 nanoseconds, but time 406 can be faster or slower as desired without departing from the scope of the present disclosure.

Time 408 is the time it takes for the waveform 402 to “settle” to a given level before it is sampled by a precision analog-to-digital (A/D) converter. Although waveform 402 appears settled after time 406, waveform 409 is a magnified view of waveform 402. The distance between lines 410 and 412, shown as distance 414, may represent a plus or minus one least significant bit (LSB) change in output 310. For example, and not by way of limitation, amplifier 300 may be a 12-bit amplifier, a 16-bit amplifier, an 18-bit amplifier, etc., and may require waveform 402 to settle within a certain amount of time to enable amplifier 300 to operate at such precision. As shown in FIG. 4, time 408, which is the “settling time” of amplifier 300, may be longer than the initial slew time shown as time 406.

Time 408 may indicate an overall settling or speed of the amplifier 300, while time 418 is a period of time that allows for the precision A/D converter to complete its conversion.

Returning to FIG. 3, cascode bias 316 is driving bias transistor 318, which holds the gate of third transistor 306 at a certain voltage. When it is desired to change the state of output 310, the voltage at the gate of third transistor 306 may be moved to a higher voltage potential, which will move the voltage at the source of third transistor 306 to a higher voltage potential.

To move the voltage present at the gate of third transistor 306, replica device 328 may be used. Replica device 328 may be similar to fourth transistor 308, however, the geometry of replica device 328 may be smaller than the comparable geometry of fourth transistor 308. When the gate of fourth transistor 308 is sent high, the gate of replica device 328 is also sent high, which then sends a current to current comparator 314. Current source 317 sets a threshold for current comparator 314, and once the current from replica device 328 is changed, the current through cascode bias 316 and the additional current from current comparator 314 combine to increase the amount of current through bias transistor 318. This changes the gate voltage of bias transistor 318 via line 330.

For example, and not by way of limitation, current source 317 may be set at a small amount of current, e.g., 5 microamps, while replica device 328 may provide only 2 microamps of current. At this operating condition, current comparator 314 is off. Once replica device 328 is turned on to a level at or above 5 microamps, which is greater than the current through current source 317, current comparator 314 begins to draw current, which then sends additional current to bias transistor 318 and begins to slew amplifier 300. Once the voltage at output 310 approaches the desired level, the voltage across fourth transistor 308 will be reduced, which then reduces the voltage across replica device 328, which then lowers the difference in current seen by comparator 314. This allows output 310 to settle at the desired voltage level. Amplifier 300 may be implemented as a fast switching amplifier as part of system 100 or other applications where fast switching between highly linear output voltages is desired. Once the current through replica device 328 is reduced below that of current source 317, current comparator 314 is turned off, which allows for cascode bias 316 to reduce the bias current through third transistor 306, which may be considered as a return to the “static” bias of amplifier 300. The operational changes that turn current comparator 314 on and off may occur within time 406 as shown in FIG. 4.

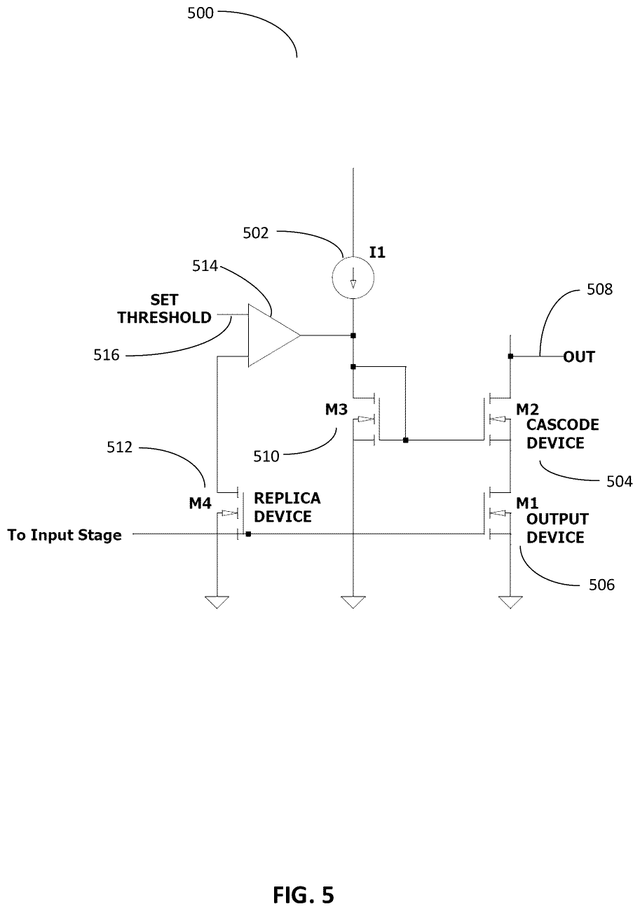

Referring to FIG. 5, a circuit 500 in accordance with an aspect of the present disclosure may include current source 502, cascode device 504, output device 506, output 508, diode-connected transistor 510, replica device 512, and comparator 514.

Current source 502 may provide a constant current in circuit 500, similar to cascode bias 316 described with respect to FIG. 3. Cascode device 504 is coupled to diode-connected transistor 510, similar to third transistor 306 described with respect to FIG. 3. Output device 506 is coupled in cascode to cascode device 504, and may be similar to fourth transistor 308 described with respect to FIG. 3. Output 508 may be similar to output 310 described with respect to FIG. 3. Diode-connected transistor 510 may be similar to diode connected transistor 318 described with respect to FIG. 3. Replica device 512 may be similar to replica device 328 described with respect to FIG. 3.

Comparator 514 has a threshold input to compare with replica device 512. Similar to the current comparator 314, once the current through replica device 512 exceeds the current threshold 516 to comparator 514, the current through cascode device 504, and thus through output device 506, is increased to allow output 508 to change state. Further, circuit 500 is one example of an n-channel metal oxide semiconductor (NMOS) portion of the principles of operation of the present disclosure. Other circuits and operations are possible without departing from the scope of the present disclosure.

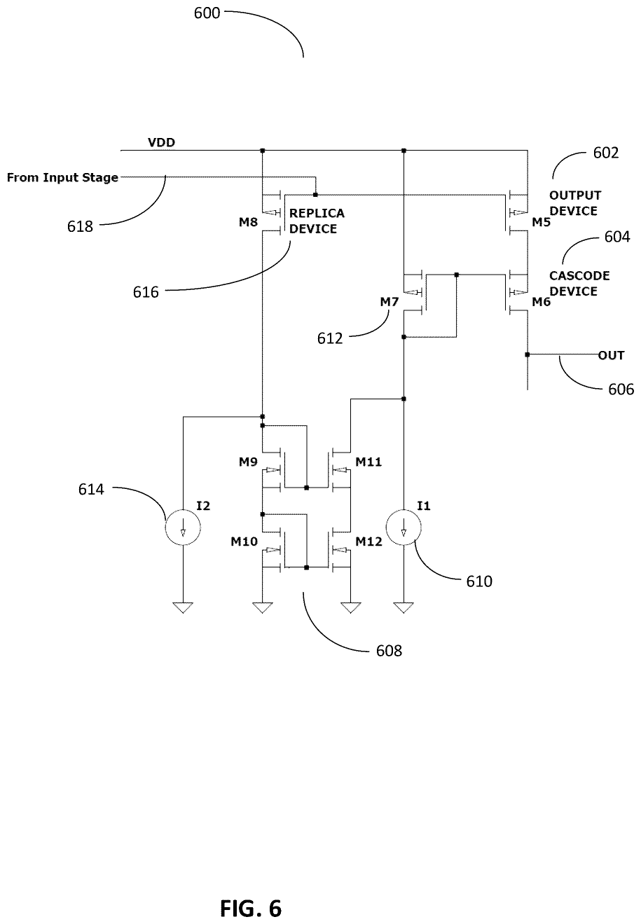

Referring to FIG. 6, a circuit 600 in accordance with an aspect of the present disclosure may include output device 602, cascode device 604, output 606, current comparator 608, cascode bias 610, diode connected transistor 612, threshold current source 614, replica device 616, and input 618. Circuit 600 may be one example of a p-channel metal oxide semiconductor (PMOS) approach to the amplifier shown in FIG. 3. Other circuits and operations are possible without departing from the scope of the present disclosure.

Output device 602 may be similar to first transistor 302 described with respect to FIG. 3. Cascode device 604 may be similar to second device described with respect to FIG. 3. Output 606 may be similar to output 310 described with respect to FIG. 3. Current comparator 608 may be similar to current comparator 314 described with respect to FIG. 3. Cascode bias 610 may be similar to cascode bias 316 described with respect to FIG. 3. Diode connected transistor 612 may be similar to diode connected transistor 318 described with respect to FIG. 3, Threshold current source 614 may be similar to current source 317 described with respect to FIG. 3. Replica device 616 may be similar to replica device 328 described with respect to FIG. 3, and input 618 may be similar to input 320 as described with respect to FIG. 3.

As discussed herein, the slew rate of the circuitry, e.g., an output buffer or circuitry as shown in FIGS. 3, 5, and 6, has a slew rate controlled based on the current through one or more of the replica devices 328, 512, and/or 616.

The previous description is provided to enable any person skilled in the art to practice the various aspects described herein. Various modifications to the exemplary aspects presented throughout this disclosure will be readily apparent to those skilled in the art, and the concepts disclosed herein may be applied in other contexts and for different purposes. Thus, the claims are not intended to be limited to the exemplary aspects presented throughout the disclosure, but are to be accorded the full scope consistent with the language claims. All structural and functional equivalents to the elements of the exemplary aspects described throughout this disclosure that are known or later come to be known to those of ordinary skill in the art are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f), or analogous law in applicable jurisdictions, unless the element is expressly recited using the phrase “means for” or, in the case of a method claim, the element is recited using the phrase “step for.”

What is claimed is:

1. An apparatus comprising:
a first transistor;
a second transistor, coupled in cascode to the first transistor;
a biasing source, coupled to the second transistor;
a replica device, coupled to the first transistor; and
a comparator, coupled to the biasing source and the replica device, wherein a slew rate of the first transistor is controlled based on a current through the replica device.

2. The apparatus of claim 1, wherein a geometry of the replica device is similar to a geometry of the first transistor.

3. The apparatus of claim 1, wherein the comparator compares a current through the biasing source with a threshold current.

4. The apparatus of claim 3, wherein when the current through the biasing source and a current through the replica device is greater than the threshold current, a voltage at a gate of the first transistor is changed to increase a current through the first transistor.

5. The apparatus of claim 4, wherein when the current through the biasing source and the current through the replica device is less than the threshold current, the voltage at the gate of the first transistor is changed to decrease the current through the first transistor.

6. The apparatus of claim 1, further comprising:
a third transistor;
a fourth transistor coupled in cascode with the third transistor; and
a second replica device coupled to the fourth transistor, wherein a slew rate of the third transistor is controlled based on a current through the second replica device.

7. The apparatus of claim 6, wherein a geometry of the second replica device is similar to a geometry of the third transistor.

8. The apparatus of claim 6, wherein the comparator compares a current through the biasing source with a threshold current.

9. The apparatus of claim 8, wherein when the current through the biasing source and a current through the second replica device is greater than the threshold current, a voltage at a gate of the fourth transistor is changed to increase a current through the fourth transistor.

10. The apparatus of claim 9, wherein when the current through the biasing source and the current through the second replica device is less than the threshold current, the voltage at the gate of the fourth transistor is changed to decrease the current through the fourth transistor.

11. The apparatus of claim 6, further comprising a capacitor coupled between the first transistor and the fourth transistor, the capacitor configured to mitigate coupling between the first transistor and the fourth transistor.

12. An output buffer, comprising:
an amplifier, comprising a first transistor and a second transistor coupled in cascode, an output of the amplifier comprising an output of the output buffer;
a current source coupled to the amplifier for biasing the amplifier;
a replica device, coupled to the amplifier, wherein the replica device receives an input to the output buffer; and
a comparator, coupled to the replica device and the current source, wherein a slew rate of the amplifier is controlled based at least on a current through the replica device.

13. The output buffer of claim 12, wherein a geometry of the replica device is similar to a geometry of the first transistor.

14. The output buffer of claim 12, wherein the comparator compares a current through the current with a threshold current.

15. The output buffer of claim 14, wherein when the current through the current source and a current through the replica device is greater than the threshold current, a voltage at a gate of the first transistor is changed to increase a current through the first transistor.

16. The output buffer of claim 15, wherein when the current through the current source and the current through the replica device is less than the threshold current, the voltage at the gate of the first transistor is changed to decrease the current through the first transistor.

17. The output buffer of claim 12, further comprising:
a third transistor;
a fourth transistor coupled in cascode with the third transistor, the third transistor coupled to the output of the output buffer; and
a second replica device coupled to the fourth transistor, wherein a slew rate of the third transistor is controlled based on a current through the second replica device.

18. The output buffer of claim 17, wherein a geometry of the second replica device is similar to a geometry of the third transistor.

19. The output buffer of claim 17, wherein the comparator compares a current through the current source with a threshold current.

20. The output buffer of claim 19, wherein when the current through the current source and a current through the second replica device is greater than the threshold current, a voltage at a gate of the fourth transistor is changed to increase a current through the fourth transistor.

21. The output buffer of claim 20, wherein when the current through the current source and the current through the second replica device is less than the threshold current, the voltage at the gate of the fourth transistor is changed to decrease the current through the fourth transistor.
